(19) United States
(12) Patent Application Publication
(10) Pub. No.: US 2026/0266299 A1
(43) Pub. Date: Sep. 10, 2026

(54) IMPROVED SELF-POWERED FAN ASSEMBLY

(71) Applicant: Randall H. REID, Ontario (CA)

(72) Inventor: Randall H. REID, Ontario (CA)

(21) Appl. No.: 19/162,308

(22) PCT Filed: Mar. 1, 2024
(86) PCT No.: PCT/CA2024/050257

§ 371 Date: Sep. 4, 2025

Related U.S. Application Data
(60) Provisional application No. 63/488,612, filed on Mar. 6, 2023.

(51) Int. Cl. F04D 25/06; H10N 10/17

(52) U.S. Cl. CPC F04D 25/06; H10N 10/17

(57) ABSTRACT

The present disclosure relates to a self-powered fan assembly comprising a lower heat exchanger, a thermoelectric generator module coupled to a motor that operates a fan, and an upper heat exchanger. The lower heat exchanger includes a first module landing with a first heat transfer surface and a heat transfer stem thermally coupling a heat source to the first module landing. A hot side of the thermoelectric generator module is thermally connected to the first heat transfer surface of the first module landing. The upper heat exchanger includes a second module landing having a second heat transfer surface which is thermally connected to a cool side of the thermoelectric generator module, a vane array for dissipating heat, and one or more heat pipes thermally coupling the second module landing to the vane array. The heat pipes allow for faster heat transfer between the second module landing and the vane array.

### FIELD

The present invention relates to heat transfer fans, and in particular, self-powered fans for use in conjunction with heated surfaces, such as fossil-fuel burning stoves.

### BACKGROUND

Heating units such as wood stoves, and other fossil-fuel combustible material burning stoves, hot water radiators, gas fireplaces, electrical heaters, and the like, disseminate heat into the surrounding space by radiation and by convection of thermal air currents circulating around the unit. Warm air distribution from the unit may be enhanced by means of an air blower or fan suitably placed on, or adjacent to, the unit. Typically, these air circulating fans are powered by an electric battery or by electrical mains power supply.

In accordance with the “Peltier Effect”, it is known that when a direct electric current is passed through a thermoelectric couple, heat will be absorbed at one end of the couple, to cause cooling thereof, and heat will be generated at the other end of the couple, and thereby cause a rise in temperature. By reversing the current flow, the direction of heat flow will be reversed.

In a similar, but reverse, manner to the Peltier Effect, a thermoelectric generator will generate an electric potential across its terminals if a temperature gradient, or thermocline, is provided across the thermoelectric generator module (the “Seebeck Thermocouple Effect”). As a result, electric power is generated by the thermocouple generator module as a function of the temperature difference, or heat gradient, across the module.

Typically, thermoelectric generators are provided in the form of a thermoelectric couple and usually comprise an array of semiconductor couples (such as bismuth telluride P and N pellets) connected electrically in series and thermally in parallel, sandwiched between ceramic or metallized ceramic substrates. Commercial products relying on the Seebeck Effect are known, and include devices such as those available from Tellurex Corporation, who provide a thermoelectric generator which, when heated by a propane torch or the like, will generate electric energy.

U.S. Pat. No. 5,544,488 and U.S. Pat. No. 7,812,245 describe air circulation fans which are powered only by thermoelectric generators that utilize the heat which is available at the heated surface of a heating unit, such as the top of a stove. The devices described therein can provide useful warm air circulation, notwithstanding the extremely low efficiency of the conversion of thermal energy to electrical energy which is inherent in the aforesaid Seebeck Thermocouple Effect.

In U.S. Pat. No. 5,544,488, a fan is placed above the thermoelectric generator module and electrical power from the module is use to turn the fan. As a result, warm air propelled forward from the unit provides warm air circulation. In addition, incoming cooler air is pulled toward the fan unit, and this cooler air acts to enhance the cooling of a heat sink cooling end. This helps to provide increased electrical current output, and reduces the heat applied to the hot end of the thermoelectric generator module.

In U.S. Pat. No. 7,812,245, an improved version of this device is provided wherein the fan motor component is located in a motor-receiving cavity located in a portion of the lower heat transfer member, so that the fan motor is located below the thermoelectric generator module. The thermoelectric generator structure is located between the lower heat transfer member, and an upper heat transfer member above the thermoelectric generator. The device is of suitable material, size, mass and shape, so as to provide an enhanced temperature gradient between the thermocouple structure and the heat source. This allows for sufficient heat transfer from the first heat transfer member to the thermoelectric generator module, in order to generate the requisite power to effect rotation of the fan motor, and thus, the fan blades.

While these self-powered fan devices have been well received in the industry, there is a desire to provide such self-powered heat transfer fans having improved performance characteristics. In particular, it would be beneficial to the industry to provide Seebeck Thermocouple Effect powered fans for use on heated surfaces, which provide increased airflow while also reducing or minimizing the temperatures observed in the motor and thermoelectric generator areas of the fan.

It should be noted, that while it might be expected in the art, that increasing the size of the thermoelectric generator module will increase the current generated, increasing the size of the module can lead to damage to the module itself cause by heat expansion across the module, and the like. As well, increasing the thermoelectric generator module size can negatively impact the efficiency of the device overall.

### SUMMARY

To address the above issues, it would be advantageous to the industry to provide a self-powered thermal fan for use on a heated surface, by application of the Seebeck Thermocouple Effect, which would provide increased power output. It would also be beneficial if this approach provided increased airflow created by the fan. This combined effect would provide greater fan efficiency, while also preferably aiding in reducing the temperatures observed in the motor and thermoelectric generator areas of the fan.

Thus, it is an advantage of the present invention to provide an improved self-powered air circulation fan, which generates its own electrical power from a temperature difference, or heat gradient, induced across distinct members of the fan.

It is a further advantage of the present invention to provide an improved self-powered air circulation fan which generates its own electrical power from an external heat source for use with such heat source, for example a fossil-fuel burning stove.

It is a yet further advantage of the present invention to provide an improved self-powered air circulation fan having a heat transfer feature which is at least partially cooled by the cooling assistance of the fan blades.

It is a still further advantage of the present invention to provide an improved self-powered air circulation fan with improved efficiency, and improved resistance to heat-related damage to the fan and circulation motor. The advantages set out hereinabove, as well as other objects and goals inherent thereto, are at least partially or fully provided by the self-powered thermal fan of the present invention, as set out herein below.

Accordingly, in a first aspect, the present disclosure provides a self-powered fan assembly comprising: a lower heat exchanger comprising: a first module landing having a first heat transfer surface; and a heat transfer stem extending between, and thermally coupling, a heat source to the first module landing; a thermoelectric generator module having a hot side and an opposed cool side, the hot side of the thermoelectric generator module being thermally connected to the first heat transfer surface of the first module landing; an electric motor electrically coupled to the thermoelectric generator module to drive the electric motor; a fan operatively coupled to the electric motor; an upper heat exchanger comprising: a second module landing having a second heat transfer surface which is thermally connected to the cool side of the thermoelectric generator module; a vane array for dissipating heat; and one or more heat pipes extending between, and thermally coupling, the second module landing to the vane array; whereby a heat gradient created across the thermoelectric generator module generates power to operate the electric motor and, thereby, the fan.

In another aspect, the present disclosure provides the above fan assembly wherein the fan comprises fan blades which, when moved by the electric motor, operably create a warm air flow away from the fan assembly, and a cooler air flow toward the fan assembly.

In another aspect, the present disclosure provides the above fan assembly wherein the one or more heat pipes each are configured to have a working range of 30° to 120° C.

In another aspect, the present disclosure provides the above fan assembly wherein the one or more heat pipes each comprise water as a working fluid sealed within a copper jacket.

In another aspect, the present disclosure provides the above fan assembly wherein the one or more heat pipes are flat heat pipes.

In another aspect, the present disclosure provides the above fan assembly wherein the one or more heat pipes are cylindrical heat pipes.

In another aspect, the present disclosure provides the above fan assembly wherein the one or more heat pipes comprise a hot interface thermally coupled to the second module landing and an opposed cold interface thermally coupled to the vane array.

In another aspect, the present disclosure provides the above fan assembly wherein the hot interface of each of the one or more heat pipes extends to a heating end, and the cold interface of each of the heat pipes extends to a cooling end.

In another aspect, the present disclosure provides the above fan assembly wherein the fan assembly comprises three heat pipes extending from the second module landing as a first arm and another three heat pipes extending from the second module landing as a second arm.

In another aspect, the present disclosure provides the above fan assembly wherein the upper heat exchanger further comprises elongate extrusions extending from the second module landing that define landing slots, the landing slots dimensioned to receive, and thermally couple with, the heating ends of the one or more heat pipes.

In another aspect, the present disclosure provides the above fan assembly wherein the hot interface of the one or more heat pipes is a curved heating portion, and a pair of cooling ends extends from the curved heating portion to the cold interface.

In another aspect, the present disclosure provides the above fan assembly wherein the upper heat exchanger further comprises a curved extrusion extending from the second module landing, the curved extrusion being correspondingly shaped to receive, and thermally couple with, the curved heating portion of the one or more heat pipes.

In another aspect, the present disclosure provides the above fan assembly wherein the vane array comprises vane slots, the vane slots dimensioned to receive, and thermally couple with, the cold interface of the one or more heat pipes.

In another aspect, the present disclosure provides the above fan assembly wherein the vane array has a concentric configuration relative to the fan.

In another aspect, the present disclosure provides the above fan assembly wherein the fan blades extend past the first module landing so as to cause a portion of the cooler air flow to be drawn past the first module landing to provide a partial cooling effect on the first module landing.

In another aspect, the present disclosure provides the above fan assembly wherein the vane array is disposed, relative to the fan blades, so that the vane array extends through the cooler air flow generated by the rotation of the fan blades.

In another aspect, the present disclosure provides the above fan assembly wherein the fan blades are positioned and orientated relative to the heat transfer stem to draw the cooler air flow past the heat transfer stem.

In another aspect, the present disclosure provides the above fan assembly wherein the heat transfer stem has a height of 5 to 20 cm.

In another aspect, the present disclosure provides the above fan assembly further comprising a base shaped for thermal connection with the heat source, the heat transfer stem extending between, and thermally coupling, the base to the first module landing.

In a further aspect, the present disclosure provides a heat source device with a self-powered fan assembly, wherein the heat source device is a fossil fuel burning device or a methane, propane or butane combustion stove, and wherein the self-powered fan assembly is the fan assembly described above, wherein the heat transfer stem is formed with, or permanently attached to, the heat source device.

### BRIEF DESCRIPTION OF THE DRAWINGS

Embodiments of this invention will now be described by way of example only in association with the accompanying drawings in which:

FIG. 1 is a front view of a prior art self-powered fan assembly;

FIG. 2 is a perspective view of the fan assembly of FIG. 1;

FIG. 3 is a front view of another prior art self-powered fan assembly;

FIG. 4 is a perspective view of the fan assembly of FIG. 3;

FIG. 5 is a front view of a self-powered fan assembly according to an example embodiment of the present disclosure;

FIG. 6 is a perspective view of the fan assembly of FIG. 5 with fan blades; and

FIG. 7 is a front, perspective view of a self-powered fan assembly according to another example embodiment of the present disclosure;

FIG. 8 is a front, perspective view of a self-powered fan assembly according to a further example embodiment of the present disclosure;

FIG. 9 is a graph illustrating the improved airflow of the fan assembly of FIG. 5 relative to the fan assembly of FIG. 3;

FIG. 10 is a graph illustrating the improved power output of the fan assembly of FIG. 5 relative to the fan assembly of FIG. 3; and

FIG. 11 is a graph illustrating the internal temperatures of a thermoelectric generator module of the fan assembly of FIG. 5.

### DESCRIPTION

The present application is primarily directed to the use of thermoelectric generators to generate electrical current to power a fan assembly, when using the fan assembly in combination with a heat source. Preferably, the heat source is a wood coal, or oil stove, or is a stove which operates by combustion of methane, propane or butane, or something similar. However, the skilled person will be aware that the fan assemblies of the present invention can be used in a wide variety of applications. Accordingly, while the present application is hereinafter described with particular reference to wood stoves, and the like, the skilled person will be well aware that the present application is equally applicable in other applications.

The novel features which are believed to be characteristic of the present invention, as to its structure, organization, use and method of operation, together with further objectives and advantages thereof, will be better understood from the following drawings in which a presently preferred embodiment of the invention will now be illustrated by way of example only. In the drawings, like reference numerals depict like elements.

It is expressly understood, however, that the drawings are for the purpose of illustration and description only and are not intended as a definition of the limits of the invention. Also, unless otherwise specifically noted, all of the features described herein may be combined with any of the above aspects, in any combination.

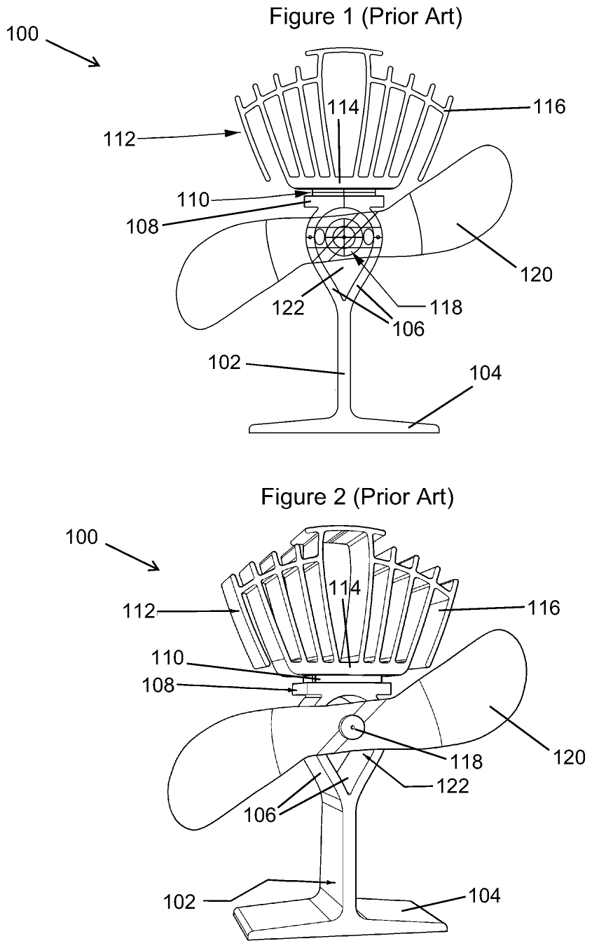

Referring to FIGS. 1 and 2, a first prior art fan assembly 100 is shown. The first prior art fan assembly 100 includes a heat transfer stem 102 connected to a base 104 which may rest on the upper surface of a heat source (not shown), such as a wood stove. Heat transfer stem 102 is integrally formed with two arms 106 and a lower module landing 108. The lower module landing 108 is in thermal communication with a thermoelectric generator module 110. The upper surface of the thermoelectric generator module 110 is in contact with a heat exchanger 112, which consists of an upper module landing 114 and an array of vanes 116.

A heat gradient may be created across the thermoelectric generator module 110, which creates an electrical current. The thermoelectric generator module 110 has an electrical connection with a motor 118, and the electrical current generated by the thermoelectric generator module 110 is used to power the motor 118 which, in turn, drives fan blades 120. In this embodiment, the base 104, heat transfer stem 102, arms 106, lower module landing 114, and heat exchanger 112, including vanes 116, may be formed from aluminum.

In the embodiment shown in FIGS. 1 and 2, the arms 106 are inwardly curved, and define a cylindrical aperture 122, which receives and retains the motor 118 therein. This arrangement allows the motor 118 to be mounted in the cylindrical aperture 122, below the lower module landing 108 and, thus, below the thermoelectric generator module 110.

Locating the motor 118 below the thermoelectric generator module 110 helps to increase the airflow through the latter, thereby helping to increase the temperature drop across the thermoelectric generator module 110 and to deliver more power to the motor 118.

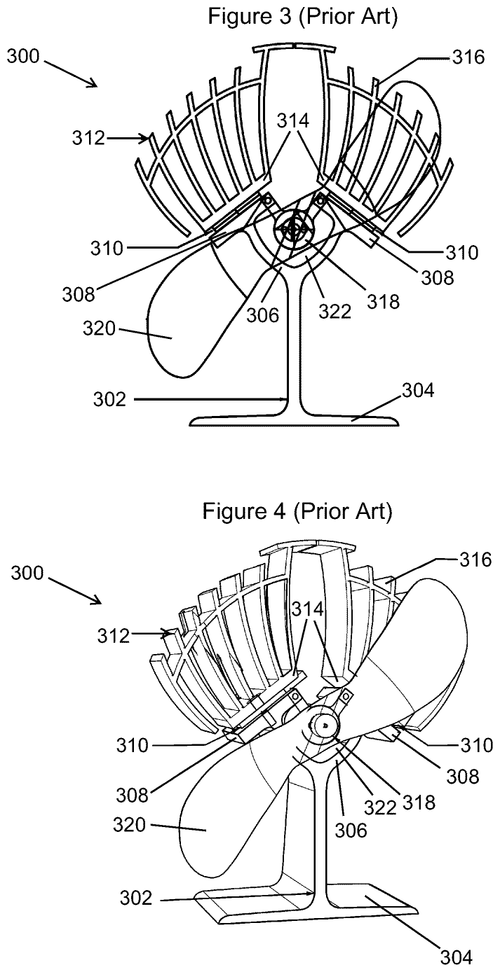

However, further power may be generated by the thermoelectric generator module 110 using a second prior art fan assembly 300 shown in FIGS. 3 and 4. The second prior art fan assembly 300 also includes a heat transfer stem 302 connected to a base 304 which may rest on the upper surface of a heat source (not shown), such as a wood stove. The heat transfer stem 302 is also integrally formed with two arms 306, however, each arm is secured to a separate lower module landing 308. Each lower module landing 308 is in thermal communication with a separate thermoelectric generator module 310. The upper surface of each of the thermoelectric generator modules 310 is in contact with a separate heat exchanger 312, which consists of an upper module landing 314 and an array of vanes 316 each.

Heat gradients may be created across both of the thermoelectric generator modules 310, which may collectively create greater electrical current than the single thermoelectric generator module in the first prior art fan assembly 100. As above, the thermoelectric generator modules 310 may be electrically connected to drive a motor 318 which, in turn, drives fan blades 320.

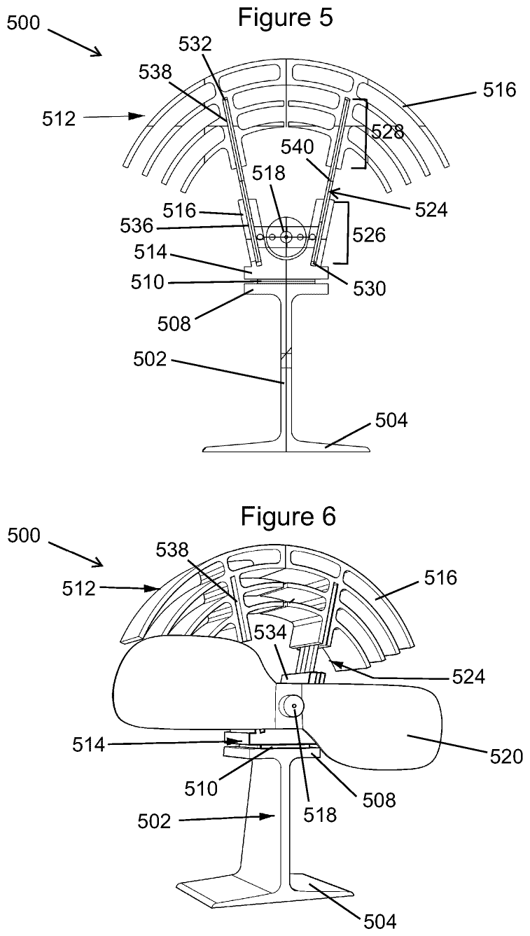

Yet additional power may be generated by the thermoelectric generator module using a fan assembly 500, an example embodiment according to the present disclosure of which is shown in FIGS. 5 and 6.

In the embodiment depicted, the fan assembly 500 includes a heat transfer stem 502 connected to a base 504 which may be adapted to rest on the upper surface of a heat source (not shown), such as a wood stove. In other applications, the fan assembly 500 may not have the base 504 and, instead, be directly secured to, or be formed as part of, the heat source device.

The heat transfer stem 502 is integrally formed in thermal communication with a lower module landing 508 at a distal end of the heat transfer stem 502. The lower module landing 508 is, in turn, in thermal communication with a lower surface (or a hot side) of a thermoelectric generator module 510. An upper surface (or a cool side) of the thermoelectric generator module 510 is in contact with a heat exchanger 512, which consists of an upper module landing 514 and an array of vanes 516.

As noted above, the thermoelectric generator module 510 may be any suitable device which can generate an electrical current resulting from the heat gradient across the module. These types of modules are known in the art, and typically and preferably rely on the Seebeck Thermocouple Effect. Commonly, the thermoelectric generator module 510 is square or rectangular in shape, and may be generally 0.5-5 cm thick. They typically have flat ceramic or metallized ceramic surfaces on their two opposite surfaces. Power is derived in the thermoelectric generator module 510, in a known manner, by preferably utilizing an array of thermocouples. Normally, the current is generated from the thermoelectric generators, and supplied to the electric motor as a direct current (DC).

The thermoelectric generator module 510 in the present case is comprised of an array of semiconductor couples (P and N pellets) connected electrically in series and thermally in parallel, sandwiched between flat metallized ceramic substrates. The lower surface (or the hot side) of the thermoelectric generator module 510 is thermally and physically connected to an upper surface (i.e. a first heat transfer surface of) the lower module landing 508, while the upper surface (or the cool side) of the thermoelectric generator module 510 is thermally and physically connected to a lower surface (i.e. a second heat transfer surface of) the upper module landing 514 of the heat exchanger 512. Heat in the upper module landing 514 is conducted to the array of vanes 516, which help to cool the lower end of the heat exchanger 512. In this embodiment, the base 504, the heat transfer stem 502, the lower module landing 508, and the heat exchanger 512, including the upper module landing 514 and the array of vanes 516, may all be extruded from aluminum. In some applications, the aluminum may be aluminum 6061 or aluminum 6063. In other applications, other thermally conductive materials may be used, such as steel, copper, and iron, or combinations thereof.

A heat gradient may be created across the thermoelectric generator module 510, which creates an electrical current. The thermoelectric generator module 510 has an electrical connection with a motor 518, and the electrical current generated by the thermoelectric generator module 510 is used to power the motor 518 which, in turn, drives fan blades 520.

In the present disclosure, notably, the fan assembly 500 further includes one or more heat pipes 524 extending between, and thermally coupling, the upper module landing 514 and the vane array 516. In some applications, the heat pipes 524 may be configured to have a working range of 30° to 120° C. For example, each of the heat pipes 524 may have a copper jacket within which is sealed water as a working fluid. In other applications, different casing materials (for example, steel or aluminum) and corresponding working fluid (for example, refrigerant or ammonia) may be used as known in the art. Each of the heat pipes 524 comprise a hot interface 526 positioned proximate, and thermally coupled, to the upper module landing 514, and an opposed cold interface 528 positioned proximate, and thermally couple, to the vane array 516.

In the embodiment shown in FIGS. 5 and 6, the hot interface 526 of each of the heat pipes 524 extends to a heating end 530, and the cold interface 528 of each of the heat pipes 524 extends to a cooling end 532. In the particularly depicted embodiment, the heat pipes 524 are flat heat pipes 540, with three flat heat pipes 540 positioned and extending from the upper module landing 514 as a first arm, and another three flat heat pipes 540 extending from the upper module landing 514 as a second arm. In some applications, the flat heat pipes 540 may measure approximately 3×8×100 mm each. In other applications, a different size or number of heat pipes 524 may be used or arranged in a different arrangement, and/or arranged into a different number of arms.

The hot interface 526 of each of the heat pipes 524 may be thermally coupled to the upper module landing 514 in one of a number of ways. In the embodiment shown in FIGS. 5 and 6, the fan assembly 500 includes elongate extrusions 534 extending from (and thermally connected to) the upper module landing 524. The elongate extrusions 534 further define landing slots 536 therein. The landing slots 536 are dimensioned to tightly receive, and physically thermally couple with, the hot interface 526 of the heat pipes 524. To that end, the hot interfaces 526 of the heat pipes 524 may be press fitted, soldered, or held with epoxy within the landing slots 536.

The vane array 516 in the depicted embodiment further has a concentric shape or configuration relative to the motor 518. It was found that the concentric arrangement helps to create a large convection surface area and less drag in the airflow. In alternate applications, other vane array shapes and configurations known in the art, such as the fence-like vane array of prior fan assemblies 100, 300 may instead be used.

The vane array 516 in the depicted embodiment further comprises vane slots 538, where the vane slots 538 are dimensioned to tightly receive, and physically thermally couple with, the cold interface 528 of the heat pipes 524. To that end, the cold interfaces 528 of the heat pipes 524 may be press fitted, soldered, or held with epoxy within the vane slots 538.

In the above applications, in use, the hot interface 526 of each of the heat pipes 524 comes in contact with the thermally conductive elongate extrusions 534 and upper landing module 514 via the landing slots 536. The water within the hot interface 526 portion of the heat pipes 524 turns into vapor by absorbing heat from the corresponding copper surface. The vapor then travels along the heat pipes 524 to the cold interface 528 portion and there condenses back into a liquid, releasing the latent heat to the vane array 516. The liquid then returns to the hot interface 526 portion through capillary action, centrifugal force, or gravity, and the cycle repeats. It was found that thermal energy from the upper landing module 514 may be transferred to the array of vanes 516 significantly faster using the heat pipes 524, than when relying solely on heat conduction through the prior art solid aluminum vanes.

As noted above, when a heat gradient is created across the thermoelectric generator module 510, this creates an electric current that drives the motor 518 which, in turn, drives the fan blades 520. The current produced is proportional to the temperature differential across the thermoelectric generator module 510. Given the faster thermal energy transfer using the heat pipes 524, a greater temperature differential may be generated/maintained across the thermoelectric generator module 510, resulting in the generation of higher electric current than that generated in prior art fan assemblies.

In some applications, the heat source may be a fossil fuel burning device which burns coal, oil or wood, or may be a stove which operates by combustion of methane, propane or butane (not shown). Temperatures on stovetops of these varieties can reach over 400° C., and such high temperatures can damage the thermoelectric generator module 510. For example, some thermoelectric generator modules have a hot-side maximum of 230° C. If the module is heated above 230° C., the bismuth teluride poles will cleave and the module will be destroyed.

Thus, as an additional advantage, when the fan blades 520 are turned by the motor 518, they operably create warm air flow away from the front of the fan assembly 500, and draw cooler air flow toward the fan assembly 500 from behind the assembly. As best seen in FIG. 6, the fan blades 520 are shown extending past the lower module landing 508 (which includes the hot-side of the thermoelectric generator module) and past at least a portion of the heat transfer stem 502. In use, this causes a portion of the cooler air flow to be drawn past the lower module landing 508 and the heat transfer stem 502 to strip heat from the heat transfer stem 502 and the lower module landing 508 before it reaches the thermoelectric generator module 510. This helps to keep the thermoelectric generator module 510 well within operational tolerances with regard to temperature.

However, as noted above, a greater temperature differential across the thermoelectric generator module 510 is desirable, as that allows for higher current to be generated. Balancing as high a temperature difference across the thermoelectric generator module 510 as possible without exceeding the hot-side threshold (which may be 230° C.) of the module is important. Thus, the type of metal used, and the size and shape of the base 504, the heat transfer stem 502, and the lower module landing 508 are specifically selected (in combination with the cooling from the fan blades 520), to regulate the heat passing through the components and attain the above-noted temperature balance. Given the ability of the present heat exchanger 512 to more quickly conduct heat from the thermoelectric generator module 510 to the vane array 516, the heat transfer stem 502 may be made shorter and/or thinner than prior art embodiments to deliver heat faster. For example, the heat transfer stem 502 may have a height of 5 to 20 cm in length and a thickness of 5 to 6 mm. In the present embodiment, the heat transfer stem 502 may be 20 cm tall with a thickness of 5.5 mm. Such a configuration has been shown to result in the lower module landing 508 having temperatures around 200° C. in use, which falls within the 230° C. threshold limit.

Moreover, the fan blades 520 are, preferably, oriented relative to the upper module landing 514 so as to cause a portion of the ambient air flow to also be drawn past the upper module landing 514, to also provide a partial cooling effect on the upper module landing 514 and the motor 518. This cooling effect is typically less than the cooling effect provided by the heat exchanger 512. In the present embodiment, it has been shown that the upper module landing 514 rarely exceeds 50° C. in use. This approach also aids in optimizing or maximizing the temperature gradient across the thermoelectric generator module 510. As understood by the skilled artisan, the greater the increase in temperature of the heat transfer stem 502 and/or the base 504, the greater the power generated by the thermoelectric generator module 510, with commensurate fan speed. Thus, increased fan speed causes faster air flow around the fan assembly 500 to enhance cooling of the motor 518 and the thermoelectric generator module 510. This overall cooling effect constitutes a useful safety feature in that it limits the heat exposure of the motor 518 and the thermoelectric generator module 510.

Fans according to the present disclosure, can typically provide satisfactory air circulation at temperature gradients across the thermoelectric generator module 510 as low as, for example, 30° C.

The fan blades 520 are shown in the depicted embodiment to also generally correspond to the height of the vane array 516. In that manner, the vane array 516 may extend through the cooler air flow (from behind the assembly) generated by the rotation of the fan blades 520 to disperse more heat therefrom.

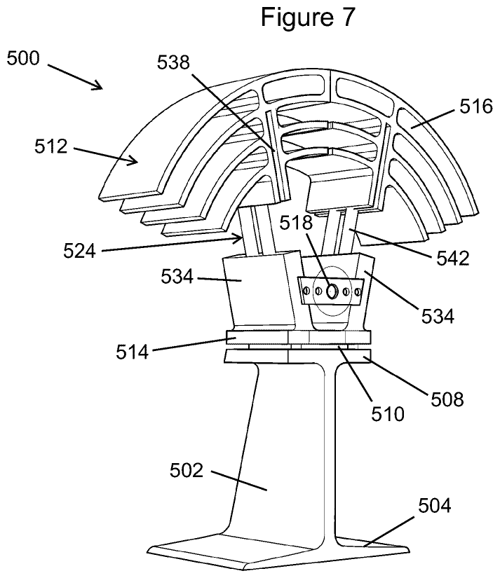

FIG. 7 illustrates a second embodiment of the fan assembly 500 according to the present disclosure. The fan assembly 500 in FIG. 7 is largely structurally and functionally similar to the fan assembly 500 of FIGS. 5 and 6, with the exception of the heat pipes 524. In the embodiment depicted in FIG. 7, the heat pipes 524 are round or cylindrical heat pipes 542, with two cylindrical heat pipes 542 positioned and extending from the upper module landing 514 as a first arm and another two cylindrical heat pipes 542 extending from the upper module landing 514 as a second arm. In that manner, the landing slots 536 (not shown) and the vane slots 538 may also be correspondingly shaped so as to tightly receive, and physically thermally couple with, the hot interfaces 526 and the cold interfaces 528 of the cylindrical heat pipes 542.

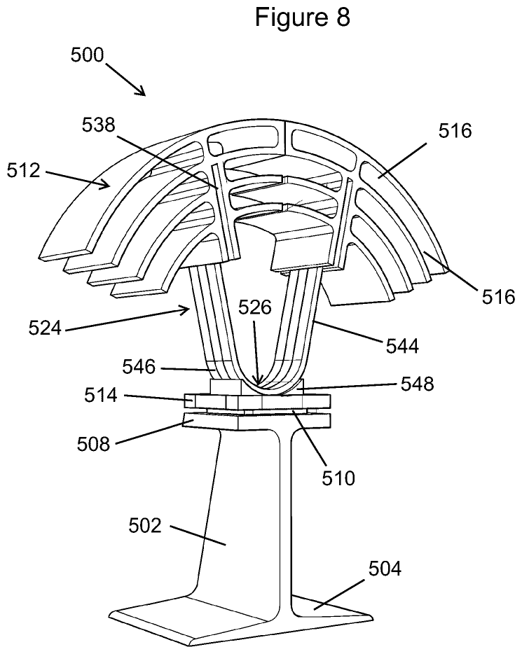

FIG. 8 illustrates a third embodiment of the fan assembly 500 according to the present disclosure. The fan assembly 500 in FIG. 8 is largely structurally and functionally similar to the fan assembly 500 of FIGS. 5 and 6, with the exception of the heat pipes 524 and the elongate extrusions 534.

In the embodiment depicted in FIG. 8, the heat pipes 524 are curved heat pipes 544, where the hot interface 526 of each of the heat pipes 524 is a curved heating portion 546, and a pair of cooling ends (hidden by the vane array 516 in FIG. 8) extends from each of the curved heating portions 546 to the cold interface (also hidden by the vane array 516 in FIG. 8).

In such an embodiment, rather than the elongate extrusions 534, the upper heat exchanger 512 may further comprise a curved extrusion 548 extending from (and thermally connected to) the upper module landing 514. The curved extrusion 548 may have a correspondingly curved segment to receive, and thermally couple with, the hot interface 526/curved heating portion 546 of the curved heat pipes 544. To that end, the curved heating portion 546 of the heat pipes 524 may be press fitted, soldered, or held with epoxy to the curved extrusion 548.

An advantage of the embodiment shown in FIG. 8 is that the hot interface 526 (i.e. the portion of the heat pipe 524 where the water within the heat pipe 524 turns into vapor) is positioned directly over the thermoelectric generation module 510, which may result in more direct and efficient heat transfer.

As noted above, the heat pipes 524 help to conduct heat from the upper module landing 514 to array of vanes 516 faster than when conducting the same heat through solid metal (such as aluminum). This has shown to result in a greater temperature difference between the hot and cold sides of the thermoelectric generator module 510 and, thus, results in considerably more electrical power being generated. The greater electrical power operates the fan blades 520 faster, which generates greater airflow, notably drawing a greater volume of cooler air flow toward the fan assembly 500, thereby helping to keep the motor 518 and the thermoelectric generator module 510 from overheating.

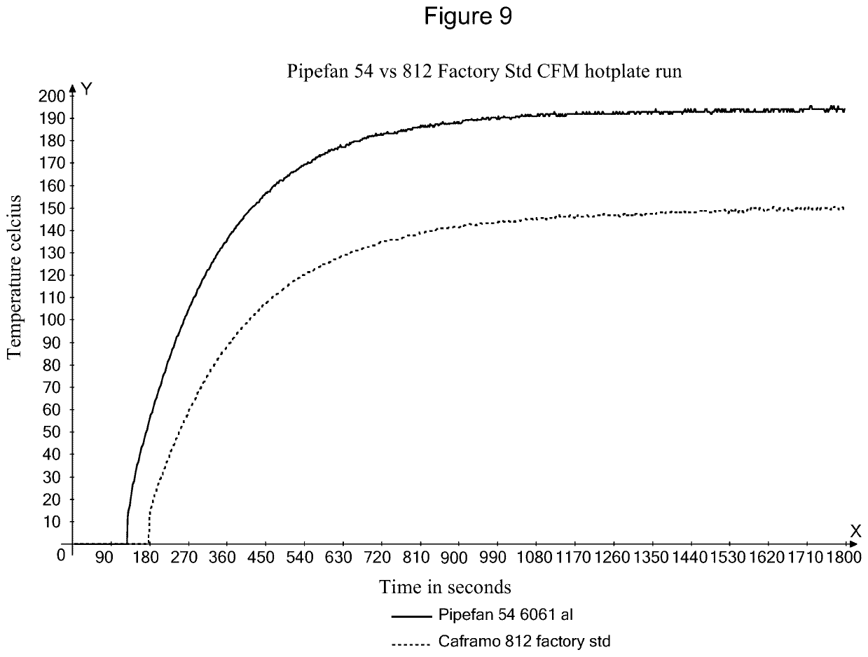

To demonstrate the improvement provided in the present disclosure, prototypes of the devices shown in FIGS. 3-4 and 5-6 were prepared and compared to each other. The tests were conducted on an electric hotplate to simulate a normal stovetop output. Both fan assembly devices were placed on a pre-heated hotplate. The electrical power generated, and the resultant air movement caused by similar motors and fan blades were recorded. The equipment monitored temperatures, voltage and current and airflow. FIGS. 9 to 11 are graphs illustrating the results.

FIG. 9 is a graph of the cubic feet per minute (cfm) delivered by the fan assembly 500 (as shown in FIGS. 5 and 6) relative to the cfm delivered by the prior art fan assembly 300 (as shown in FIGS. 3 and 4). As can be seen from the graph, the fan assembly 500 produces almost 25% more airflow than the prior art fan assembly 300. The fan assembly 500 is shown starting at a lower temperature and delivering more airflow at lower temperatures.

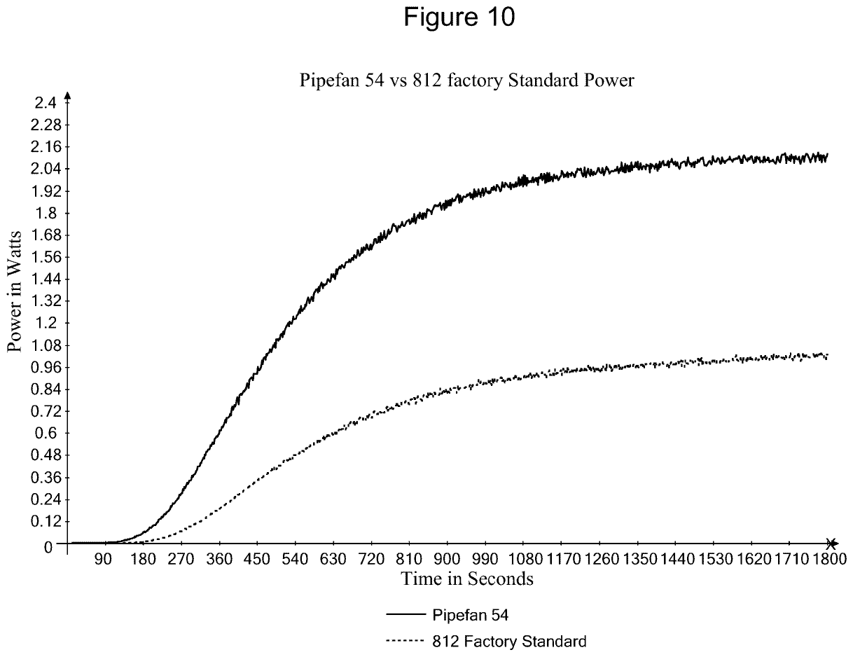

FIG. 10 is a graph illustrating the improved power output of the fan assembly 500 (as shown in FIGS. 5 and 6) relative to that of the prior art fan assembly 300 (as shown in FIGS. 3 and 4). The power developed by the fan assembly 500 is over twice as high as that of the prior art fan assembly 300.

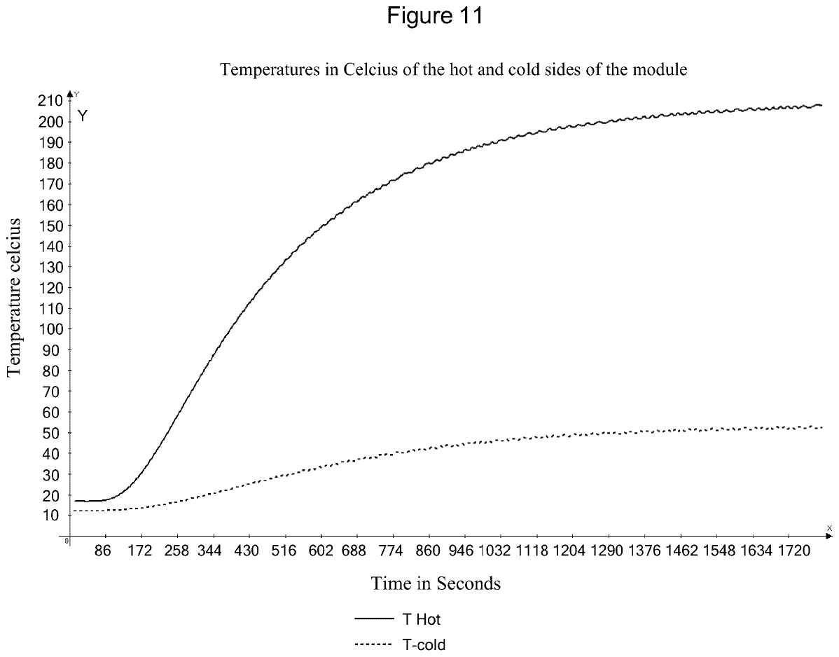

FIG. 11 is a graph illustrating the internal temperatures of the thermoelectric generator module 510 (as shown in FIGS. 5 and 6) in use. FIG. 11 shows that the thermoelectric generator module 510 stays well within its operational temperature limits (i.e. below 230° C.).

As such, it is clear that the fan assembly 500 of the present disclosure provides improved performance over the prior art devices.

The fan assembly 500 preferably draws all of its power from the thermoelectric generator module 510, and thus requires no external electrical power source. As a consequence of this arrangement, the fan assembly 500 stops, starts and runs automatically depending on the temperature of the heated source. The fan assembly 500 also provides variable air circulation in proportion to the amount of heat provided to the lower module landing 508 and resultant thermocline, or heat gradient, across the thermoelectric generator module 510.

This disclosure has now described and illustrated certain preferred embodiments of the invention which are superior to the prior art devices. However, it is to be understood that the invention is not restricted to those particular embodiments shown in the figures. Rather, the invention includes all embodiments which are functional or mechanical equivalence of the specific embodiments and features that have been described and illustrated.

Thus, it is apparent that there has been provided, in accordance with the present invention, a self-powered thermal fan assembly which fully satisfies the goals, objects, and advantages set forth hereinbefore. Therefore, having described specific embodiments of the present invention, it will be understood that alternatives, modifications and variations thereof may be suggested to those skilled in the art, and that it is intended that the present specification embrace all such alternatives, modifications and variations as fall within the scope of the appended claims.

Additionally, for clarity and unless otherwise stated, the word “comprise” and variations of the word such as “comprising” and “comprises”, when used in the description and claims of the present specification, is not intended to exclude other additives, components, integers or steps. Further, the invention illustratively disclosed herein suitably may be practiced in the absence of any element which is not specifically disclosed herein.

Moreover, words such as “substantially” or “essentially”, when used with an adjective or adverb is intended to enhance the scope of the particular characteristic; e.g., substantially planar is intended to mean planar, nearly planar and/or exhibiting characteristics associated with a planar element.

Further, use of the terms “he”, “him”, or “his”, is not intended to be specifically directed to persons of the masculine gender, and could easily be read as “she”, “her”, or “hers”, respectively.

Also, while this discussion has addressed prior art known to the inventor, it is not an admission that all art discussed is citable against the present application.

What is claimed is:

1. A self-powered fan assembly comprising:
a lower heat exchanger comprising:
a first module landing having a first heat transfer surface; and
a heat transfer stem extending between, and thermally coupling, a heat source to the first module landing;
a thermoelectric generator module having a hot side and an opposed cool side, the hot side of the thermoelectric generator module being thermally connected to the first heat transfer surface of the first module landing;
an electric motor electrically coupled to the thermoelectric generator module;
a fan operatively coupled to the electric motor;
an upper heat exchanger comprising:
a second module landing having a second heat transfer surface which is thermally connected to the cool side of the thermoelectric generator module;
a vane array for dissipating heat; and
one or more heat pipes extending between, and thermally coupling, the second module landing to the vane array;
whereby a heat gradient created across the thermoelectric generator module generates power to operate the electric motor and, thereby, the fan.

2. The fan assembly of claim 1, wherein the fan comprises fan blades which, when moved by the electric motor, operably create a warm air flow away from the fan assembly, and a cooler air flow toward the fan assembly.

3. The fan assembly of claim 2, wherein the one or more heat pipes each are configured to have a working range of 30° to 120° C.

4. The fan assembly of claim 3, wherein the one or more heat pipes each comprise water as a working fluid sealed within a copper jacket.

5. The fan assembly of claim 2, wherein the one or more heat pipes are flat heat pipes.

6. The fan assembly of claim 1, wherein the one or more heat pipes comprise a hot interface thermally coupled to the second module landing and an opposed cold interface thermally coupled to the vane array.

7. The fan assembly of claim 6, wherein the hot interface of each of the one or more heat pipes extends to a heating end, and the cold interface of each of the heat pipes extends to a cooling end.

8. The fan assembly of claim 7, wherein the fan assembly comprises three heat pipes extending from the second module landing as a first arm and another three heat pipes extending from the second module landing as a second arm.

9. The fan assembly of claim 7, wherein the upper heat exchanger further comprises elongate extrusions extending from the second module landing that define landing slots, the landing slots dimensioned to receive, and thermally couple with, the heating ends of the one or more heat pipes.

10. The fan assembly of claim 6, wherein the flat heat pipes have dimensions of 3×8×100 mm.

11. The fan assembly of claim 6, wherein the hot interface of the one or more heat pipes is a curved heating portion, and a pair of cooling ends extends from the curved heating portion to the cold interface.

12. The fan assembly of claim 11, wherein the upper heat exchanger further comprises a curved extrusion extending from the second module landing, the curved extrusion being correspondingly shaped to receive, and thermally couple with, the curved heating portion of the one or more heat pipes.

13. The fan assembly of claim 6, wherein the vane array comprises vane slots, the vane slots dimensioned to receive, and thermally couple with, the cold interface of the one or more heat pipes.

14. The fan assembly of claim 1, wherein the one or more heat pipes are cylindrical heat pipes.

15. The fan assembly of claim 1, wherein the vane array has a concentric configuration relative to the fan.

16. The fan assembly of claim 2, wherein the heat transfer stem has a height of 5 to 20 cm.

17. The fan assembly of claims 1, further comprising a base shaped for thermal connection with the heat source, the heat transfer stem extending between, and thermally coupling, the base to the first module landing.

18. A heat source device with a self-powered fan assembly, wherein the heat source device is a fuel burning device, and wherein the self-powered fan assembly is the fan assembly as claimed in claim 1, wherein the heat transfer stem is formed with, or permanently attached to, the heat source device.
